(19) United States
(12) Patent Application Publication
(10) Pub. No.: US 2006/0180926 A1
(43) Pub. Date: Aug. 17, 2006

(54) Heat spreader clamping mechanism for semiconductor modules

(75) Inventors: Donald R. Mullen, Mountain View, CA (US); Ming Li, Fremont, CA (US)

Correspondence Address: MORGAN LEWIS & BOCKIUS LLP/RAMBUS INC., 2 PALO ALTO SQUARE, 3000 EL CAMINO REAL, PALO ALTO, CA, 94306, US

(73) Assignee: Rambus, Inc.

(21) Appl. No.: 11/056,536

(22) Filed: Feb. 11, 2005

(51) Int. Cl. H01L 23/495

(52) U.S. Cl. 257/727

(57) ABSTRACT

The semiconductor module includes a circuit board substrate, multiple semiconductor devices, a layer of thermal interface material, a heat spreader, and a heat spreader clamping mechanism. Each semiconductor device has a semiconductor first side coupled to the substrate, and a semiconductor second side opposing the semiconductor first side. The thermal interface material has a thermal interface material first side at least partially covering the semiconductor second side, and a thermal interface material second side opposing the thermal interface material first side. The heat spreader has a heat spreader first side contacting the thermal interface material second side, and a heat spreader second side opposing the heat spreader first side. The heat spreader clamping mechanism includes at least one clamp coupled to the heat spreader. The heat spreader clamping mechanism is configured to force the heat spreader first side against the thermal interface material with a substantially uniform pressure across all of the semiconductor devices.

### TECHNICAL FIELD

The embodiments disclosed herein relate to a semiconductor module, and in particular to a heat spreader clamping mechanism for facilitating dissipation of heat away from a semiconductor module.

### BACKGROUND

As computer systems evolve, so does the demand for increased semiconductor processing power, capacity and operating frequency. However, increases in semiconductor processing power, capacity and operating frequency typically come at a cost, namely an increase in the power consumption of the semiconductor devices. Besides the obvious drawbacks of increased energy costs and shorter battery life, increased power consumption also leads to significantly higher operating temperatures of the semiconductor devices. These higher operating temperatures adversely affect the semiconductor devices' operation. Accordingly, as much heat as possible should be dissipated away from the semiconductor devices during operation.

These problems are exacerbated in computer systems that use a combination of multiple semiconductor devices. Such multiple semiconductor devices are often bundled into a single package, otherwise known as a semiconductor module. Such semiconductor modules are particularly prevalent in the memory industry, where multiple memory devices are packaged into discrete memory modules. However, the close confinement of the semiconductor devices in a semiconductor module package compounds the excess heat problems and makes heat dissipation difficult.

Moreover, many semiconductor modules, such as dual in-line memory modules or DIMMs, are electrically and mechanically coupled to a computer motherboard using an in-line socket connector. However, the in-line socket connector usually acts as a thermal insulator between the DIMM and motherboard. Accordingly, the heat generated by the semiconductor devices can only be dissipated to the ambient air.

Not only has the demand for increased processing power and memory been increasing rapidly, but there has also been a steady increase in the demand for smaller modules having the same processing power, capacity and/or operating frequency. Such smaller modules necessitate an increase in the density of the semiconductor devices within the semiconductor module. However, any increase in the density of the semiconductor devices within a module also exacerbates the heat generation and dissipation problems.

Accordingly, a system and method to more effectively dissipate heat from a semiconductor module would be highly desirable.

### BRIEF DESCRIPTION OF THE DRAWINGS

For a better understanding of the nature and objects of the invention, reference should be made to the following detailed description taken in conjunction with the accompanying drawings, in which:

FIG. 1A is a side view of a semiconductor module and thermal interface material, according to an embodiment of the invention;

FIG. 1B is a side view of the semiconductor module shown in FIG. 1A with the thermal interface material applied thereto, as well as a separate heat spreader;

FIG. 1C is a side view of the semiconductor module of FIG. 1B with the heat spreader applied thereto and a separate heat spreader clamping mechanism;

FIG. 1D is a side view of the assembled semiconductor module of FIG. 1C, where the heat spreader and heat spreader clamping mechanism are applied to the semiconductor module;

FIG. 2A is a partial cross-sectional view of one side of the assembled semiconductor module as taken along line 2-2′ of FIG. 1D;

FIG. 2B is a partial cross-sectional view of one side of another assembled semiconductor module, according to another embodiment of the invention;

FIG. 3 is a partial cross-sectional view of one side of yet another assembled semiconductor module, according to yet another embodiment of the invention;

FIGS. 4A and 4B are three dimensional and side views, respectively, of another heat spreader clamping mechanism, according to another embodiment of the invention;

FIGS. 5A and 5B are three dimensional and side views, respectively, of yet another heat spreader clamping mechanism, according to yet another embodiment of the invention;

FIGS. 6A and 6B are three dimensional and side views, respectively, of one other heat spreader clamping mechanism, according to one other embodiment of the invention;

FIGS. 7A and 7B are two further embodiments of heat spreader clamping mechanisms, according to two other embodiments of the invention; and

FIG. 8 is a block diagram of a system that utilizes the heat spreader clamping mechanism for a semiconductor module, according to an embodiment of the present invention.

Like reference numerals refer to the same or similar components throughout the several views of the drawings.

### DETAILED DESCRIPTION OF THE EMBODIMENTS

The following description details various systems for dissipating heat from a semiconductor module disposed within a computing system. In some embodiments, the semiconductor module includes multiple semiconductor devices thermally coupled to a heat spreader or heat sink. The heat spreader is used to dissipate heat away from the semiconductor devices.

To increase the thermal coupling between the semiconductor devices and the heat spreader, good mechanical contact should be made with semiconductor devices and the heat spreader. Accordingly, a thin layer of soft, compliant and thermally conductive thermal interface material (TIM) is applied between semiconductor devices and the heat spreader. The TIM acts as an interface between the heat spreader and the semiconductor devices.

The TIM typically performs best under a contact pressure, i.e., the thermal conductivity of the TIM increases with the increase of contact pressure on it. Accordingly, in some embodiments a heat spreader clamping mechanism is provided to mechanically couple the heat spreader to the TIM with a predetermined contact pressure. In other words, the heat spreader clamping mechanism applies a contact force to the heat spreader which is in turn transferred to the TIM. This contact force is optimized to increase the thermal conductivity between the semiconductor devices and the heat spreader. In most embodiments, the contact force is as large as possible without physically damaging the semiconductor devices.

The heat spreader clamping mechanism may include multiple clamps, each having a pair of clamping arms resiliently coupled to, and biased towards, one another. In other words, the arms have a preloaded spring force that biases them towards one another. The clamping arms force the heat spreader against the thermal interface material with a substantially uniform pressure. In some embodiments, this uniform pressure is between 10-40 psi, more preferably between 20-30 psi, and most preferably between 22-28 psi. The uniform pressure reduces air-gaps between the TIM and the heat spreader, and air-gaps between the TIM and the semiconductor devices, thereby increasing thermal conductivity between these components. Accordingly, these systems increase overall heat dissipation from the semiconductor module by facilitating heat dissipation through the thermal interface material and the heat spreader. This increased heat dissipation lowers the operating temperature of the semiconductor module, thereby reducing malfunctions and increasing the life of the semiconductor devices. The increased heat dissipation allows the semiconductor devices to operate at higher frequencies, to have a higher capacity and to be located physically closer to one another within the semiconductor module.

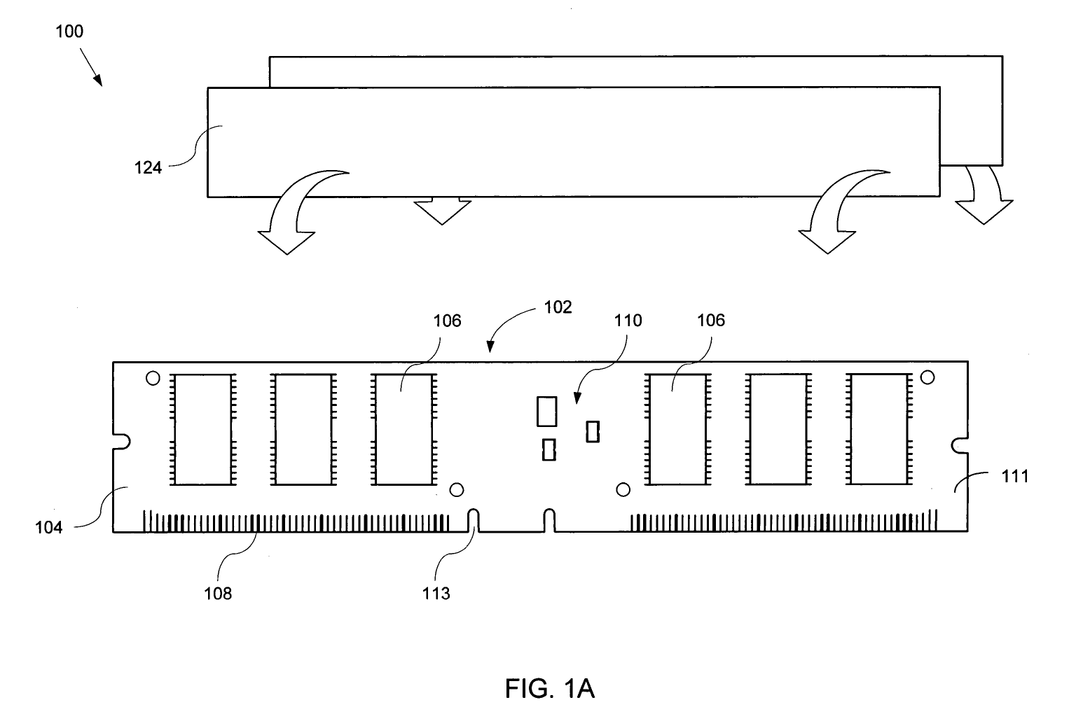

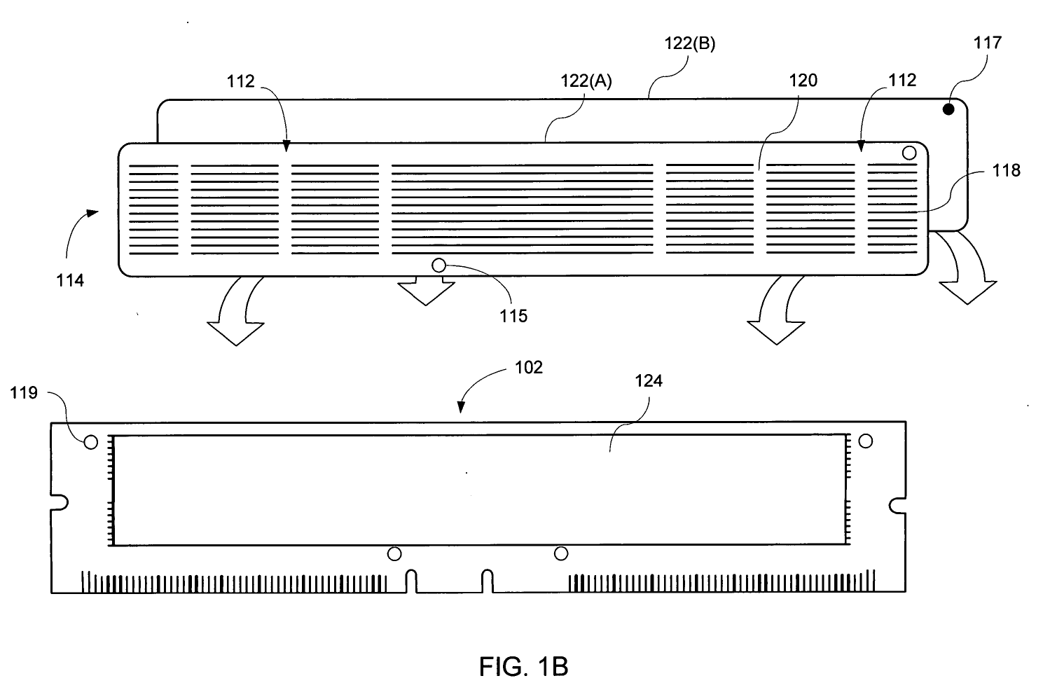

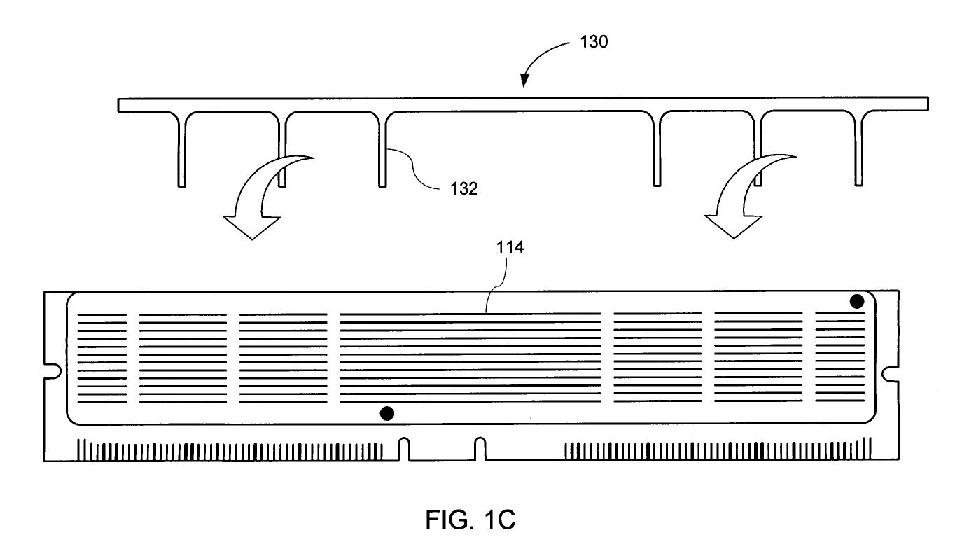

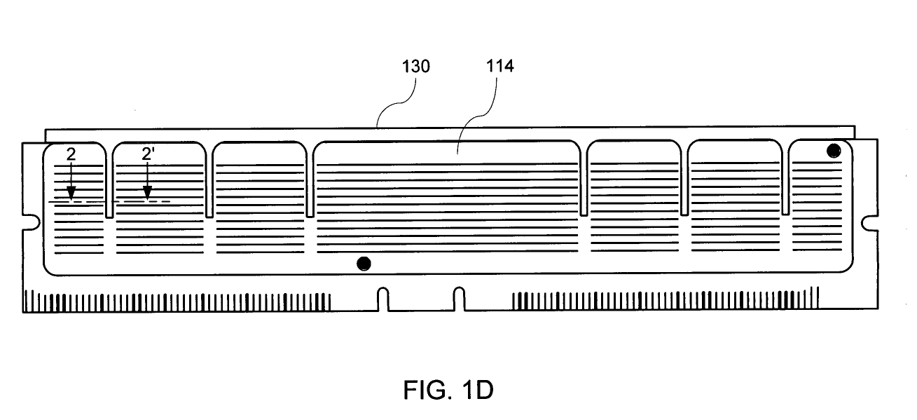

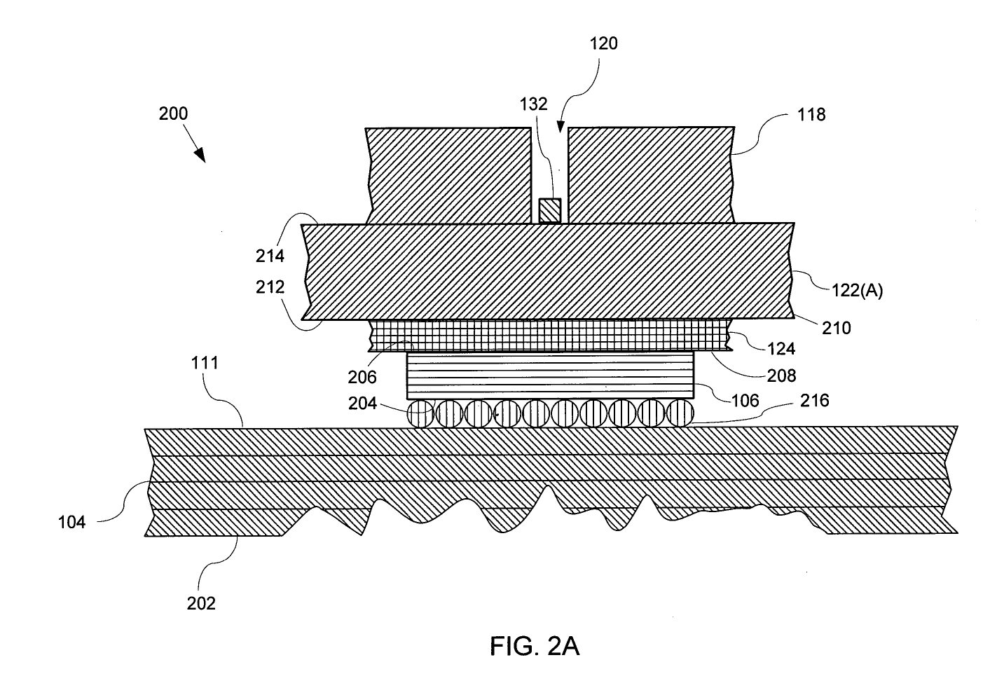

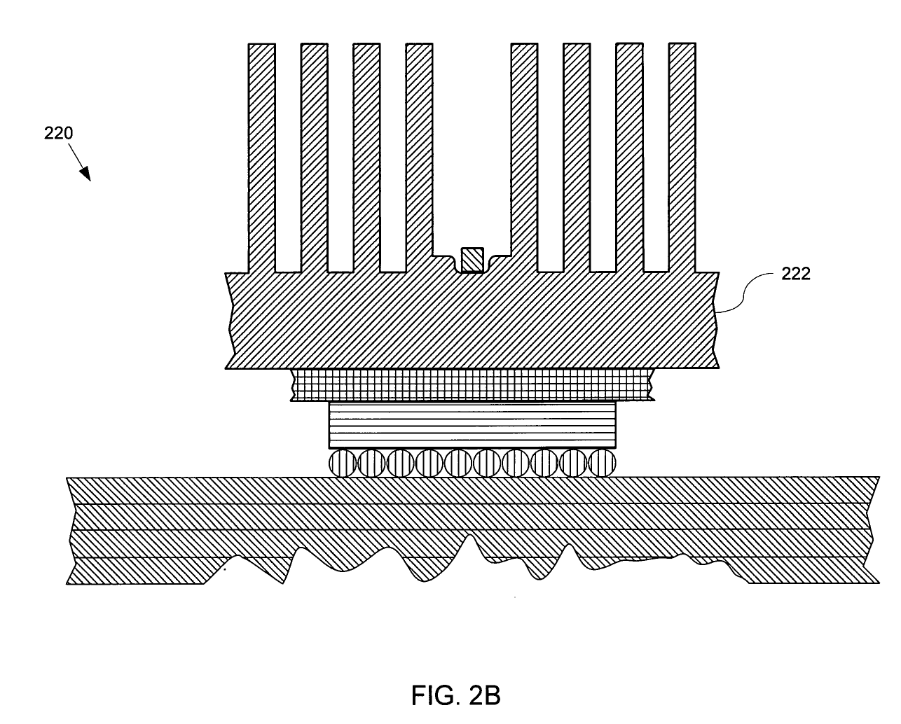

FIG. 1A is a side view 100 of a semiconductor module 102 and thermal interface material 124. The semiconductor module 102 includes a circuit board substrate 104, multiple semiconductor devices 106, a card-edge connector 108, and other circuitry and components 110. In some embodiments, the circuit board substrate 104 is a multi-layer printed circuit board (PCB), such as a FR-4 circuit board. The circuit board substrate 104 has two substantially flat opposing sides, including a first side 111 and an opposing second side 202 (FIG. 2). In some embodiments, the card-edge connector 108 is located along one edge of the circuit board substrate, on one or both the first and second sides of the substrate 104. Furthermore, in some embodiments, keyed slots 113 are provided in the circuit board substrate 104 to ensure that the semiconductor module is inserted with the correct orientation into a mating female in-line socket connector.

The semiconductor devices 106 are any integrated circuits, such as memory devices, that are each electrically and mechanically coupled to the circuit board substrate 104 along the substrate's first and/or second sides. The semiconductor devices may be coupled to the circuit board substrate via any suitable means, such as ball-grid arrays (BGAs) or the like. The semiconductor devices may also be electrically coupled to the card-edge connector 108.

During assembly of the semiconductor module 102, a strip or sheet of the thermal interface material (TIM) 124 is placed over the semiconductor devices, as described in further detail below in relation to FIG. 2. In some embodiments, the thermal interface material substantially covers the entire exposed side of each semiconductor device. If the opposing side of the semiconductor module also has semiconductor devices coupled thereto, another strip or sheet of thermal interface material is placed over the semiconductor devices on the opposing side of the semiconductor module (not shown). In an alternative embodiment, separate and distinct patches of thermal interface material may be placed over each semiconductor device. In yet another embodiment, a wet thermal interface material may be deposited onto each semiconductor device 106.

The thermal interface material (TIM) 124 is any thermally conductive material. The TIM may include a base of silicone selected for its compliant properties, and silica or alumina selected for their thermal conductivity properties. In some embodiments, the TIM is about 0.5 mm thick. Also in some embodiments, the TIM may be a fluidic material that sets or cures hard. In other embodiments, the TIM may be a material having viscosity, elasticity or resiliency, or a material that has viscosity, elasticity or resiliency once set or cured. Suitable TIM includes: the T-FLEX 200 VO SERIES material made by THERMAGON, INC; the HEATPATH GTQ R100 material made by RAYCHEM CORPORATION (HEATPATH product line acquired by DOW CORNING in 2003).

FIG. 1B is a side view of the semiconductor module 102 shown in FIG. 1A with the thermal interface material (TIM) 124 applied thereto. A heat spreader 114 is also shown. The heat spreader 114 includes a first part 122(A) and a second part 122(B). In some embodiments, the first and second parts of the heat spreader are identical to one another. The heat spreader 114 is configured to dissipate heat away from the semiconductor devices 106 (FIG. 1A) to the ambient air. The heat spreader 114 is made from any suitable thermally conductive material, such as aluminum, copper, magnesium or their alloys.

In some embodiments, the heat spreader 114 may include multiple heat spreader fins 118 to dissipate heat away from the heat spreader 114. In some embodiments, the thickness of the heat spreader is based on the pitch between semiconductor modules or female card-edge connector slots. Also in some embodiments, each part of the heat spreader 114 includes multiple guides 112. Each guide 112 is used to align a clamp directly above a respective semiconductor device 106 (FIG. 1A). In some embodiments the guides 112 include elongate guides or slots 120 therein for receiving, guiding and positioning the clamps. The guides or slots 120 may be formed between the heat spreader fins 118, as shown, or may be U-shaped slots or the like. In other embodiments, each part of the heat spreader may include small dimples directly above the center of each semiconductor device for receiving a contact of a respective clamp therein. In yet other embodiments, the guides 112 may embossed into each part of the heat spreader 114.

In some embodiments, the interior surface of the each of the first part 122(A) and a second part 122(B), i.e, the heat spreader first side 212 (FIG. 2), includes one or more alignment pins 117. Conversely, each of the first part 122(A) and a second part 122(B) and the semiconductor module, includes one or more alignment holes 115 and 119 sized to receive the alignment pins 117. In use, the alignment pins mate within the alignment holes to align the first part 122(A) and the second part 122(B) with respect to one another and with respect to the semiconductor module 102, as shown in FIGS. 1C and 1D.

During assembly, the two parts of the heat spreader are placed over the thermal material 124 on each side of the semiconductor module, such that the circuit board substrate and semiconductor devices are sandwiched between the two parts of the heat spreader.

FIG. 1C is a side view of the semiconductor module of FIG. 1B with the heat spreader 114 applied thereto. During assembly, a separate heat spreader clamping mechanism 130 is applied over the two parts of the heat spreader 114. The heat spreader clamping mechanism 130 may include multiple clamps 132. The clamps 132 may be connected to one another, as shown, or may be separate clamps, as described below. Each clamp has a pair of clamping arms resiliently coupled to, and biased towards, one another, such that the clamping arms force the heat spreader against the thermal interface material with a substantially uniform pressure, as described below.

FIG. 1D is a side view of the assembled semiconductor module of FIG. 1C. As shown, the heat spreader 114 is fixed into position by the heat spreader clamping mechanism 130.

FIG. 2A is a partial cross-sectional view of one side of the assembled semiconductor module 200. The semiconductor module 200 is similar to the assembled semiconductor module shown in FIG. 1C. The cross-sectional view is taken along line 2-2′ of FIG. 1D, and shows the cross-section for only a single semiconductor device. However, it should be appreciated that the same structure applies to multiple semiconductor devices can be applied to either or both sides of the circuit board substrate.

The partial cross-sectional view shows the circuit board substrate 104, the semiconductor device 106, the thermal interface material (TIM) 124 and the first part 122(A) of the heat spreader 114 (FIG. 1B). As shown, the circuit board substrate consists of two opposing sides, namely the substrate first side 111 and the substrate second side 202. The semiconductor device 106 also includes two opposing sides, namely a semiconductor first side 204 and a semiconductor second side 206. The thermal interface material also includes two opposing sides, namely a thermal interface material first side 208 and a thermal interface material second side 210. Finally, the first part of the heat spreader 114 includes a heat spreader first side 212 and a heat spreader second side 214.

The semiconductor first side 204 is electrically and mechanically coupled to the substrate first side 111, such as via a ball grid array (BGA) 216, as is well understood in the art. The thermal interface material first side 208 at least partially covers the semiconductor second side 206. In some embodiments, the thermal interface material first side 208 completely covers the semiconductor second side 206. The first side of the first part 122(A) of the heat spreader 114 contacts the thermal interface material second side 210.

In some embodiments, the thermal interface material 124 has adhesive properties, and adheres to the semiconductor second side 206 and the heat spreader first side 212. In other embodiments, the thermal interface material 124 is applied wet to the semiconductor device, the semiconductor first side 204 placed into contact with the wet thermal interface material 124, and the thermal interface material cured into a solid or semi-solid material.

Also as shown, the heat spreader second side 214 includes the heat spreader fins 118 that define a slot 120 into which an arm of the clamp 132 is received.

FIG. 2B is a partial cross-sectional view of one side of an alternative embodiment of an assembled semiconductor module 220. This embodiment is identical to the embodiment shown in FIG. 2A, except in this embodiment, the heat spreader fins 222 are disposed perpendicular to the orientation of the heat spreader fins 118 of FIGS. 1A-D and 2A.

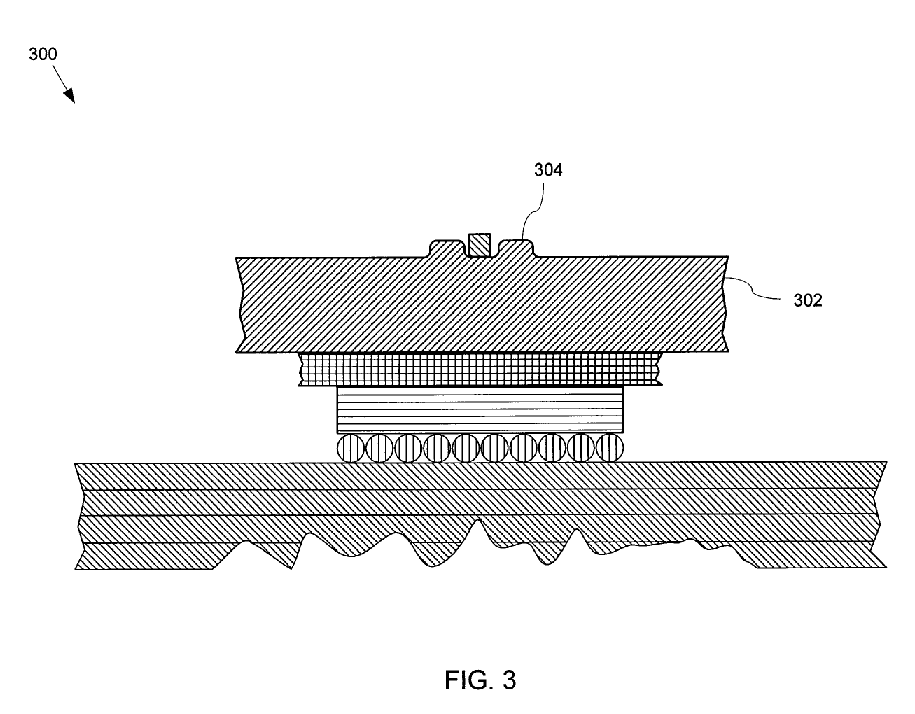

FIG. 3 is a partial cross-sectional view of one side of another assembled semiconductor module 300. This figure is similar to FIGS. 2A and 2B, except here the heat spreader 302 includes parallel ridges 304 that define a guide or slot between which each of the clamps are restrained. These ridges 304 ensure that the clamps are positioned above each of the semiconductor devices.

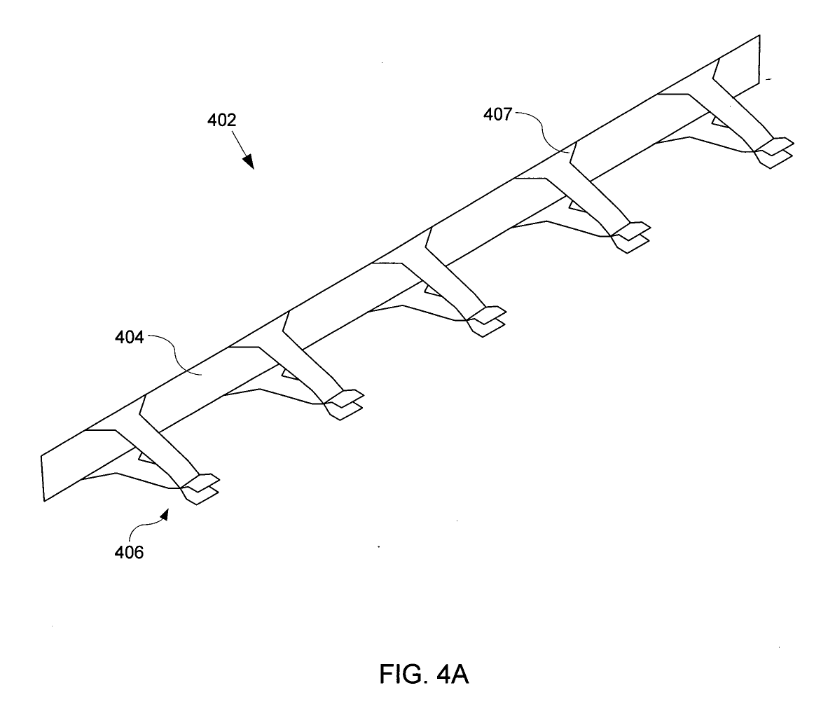

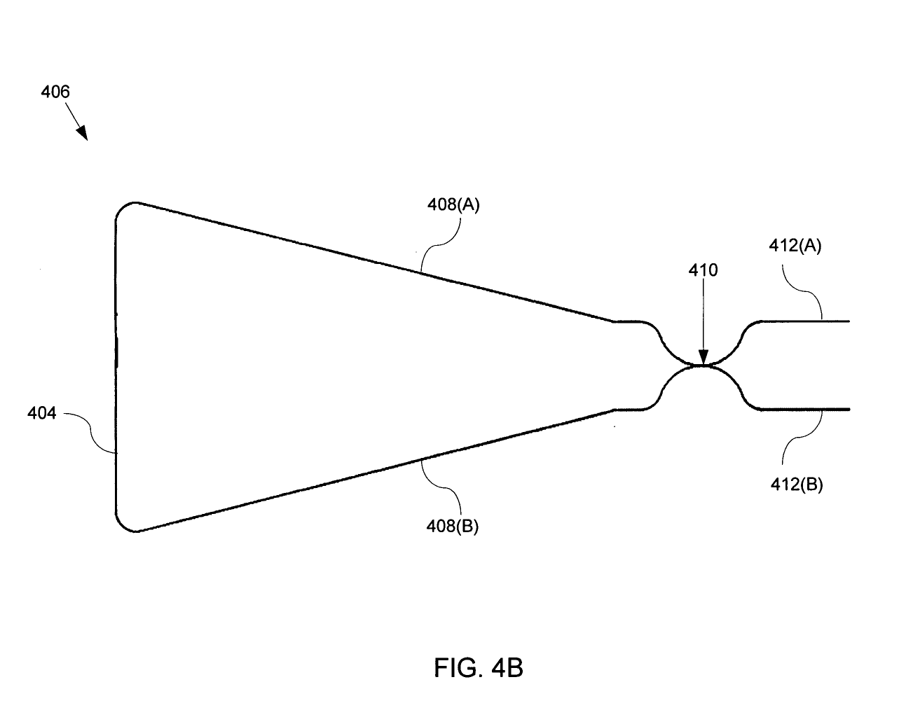

FIGS. 4A and 4B are three dimensional and side views, respectively, of another heat spreader clamping mechanism 402, according to another embodiment of the invention. The heat spreader clamping mechanism 402 includes multiple clamps 406. In some embodiments, the number of clamps 406 is the same as the same as the number of semiconductor devices on each side of the semiconductor module. For example, if there are five semiconductor devices mirroring one another on each side of the circuit board substrate, then five clamps 406 are provided. The clamps 406 are coupled to one another via a common spine 404. As shown in FIG. 4B, each clamp includes a pair of clamping arms 408(A) and 408(B) resiliently coupled to one another at the common spine 404. The arms are biased towards one another with a force sufficient to apply a uniform pressure to the heat spreader. The uniform pressure applied to the heat spreader is transferred to thermal interface material. In some embodiments, the uniform pressure applied to the thermal interface material is between 10-40 psi, more preferably between 20-30 psi, and most preferably between 22-28 psi.

In some embodiments, each arm flares 407 where it couples to the spine 404. This flared section of the arms reduces the concentrated stresses generated at the junction between the arms and the spine. In some embodiments, the arms are shaped such that when not applied to the heat spreader, they contact one another at a contact 410 (FIG. 4B). In some embodiments, this contact 410 is a contact line on each arm, while in other embodiments, the contact 410 is a contact point on each arm. The contact each arm makes with the other is the same as the contact that is made with the heat spreader. In some embodiments, contact is made with the heat spreader at the center of each semiconductor device 106 (FIG. 1A), e.g., the center of an area of the semiconductor device that is exposed to the TIM.

When applying the clamp to the heat spreader, the ends 412(A) and 412(B) of each of the arms 408(A) and 408(B) are forced open and away from one another so that the arms can straddle the heat spreader. A special tool may be required to force the arms 408(A) and 408(B) open when applying the heat spreader clamping mechanism to the heat spreader.

In some embodiments, the heat spreader clamping mechanism 402 is fabricated using a stamping process to shape and bend 0.5 mm thick stainless steel sheet metal, such as 301 stainless steel (SS301) sheet metal. This fabrication is cost effective, as instead of making individual clamps, the entire heat spreader clamping mechanism is fabricated at once. The number of the individual clamps and the shape and size of the individual clamps were calculated to reach the optimized contact pressure using an ANSYS Finite Element Analysis (FEA) method.

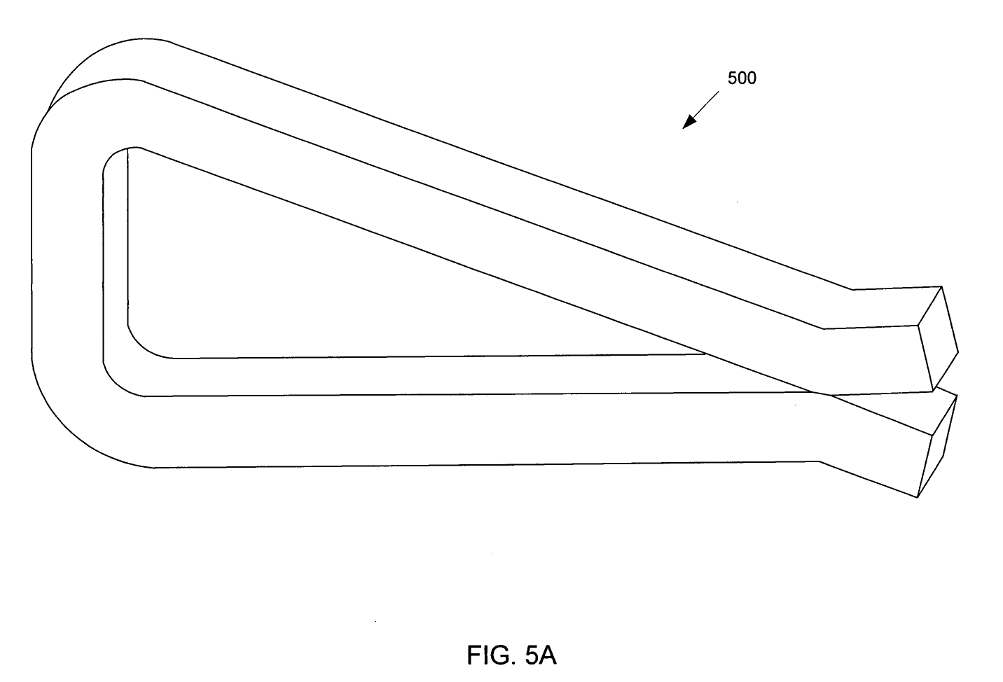

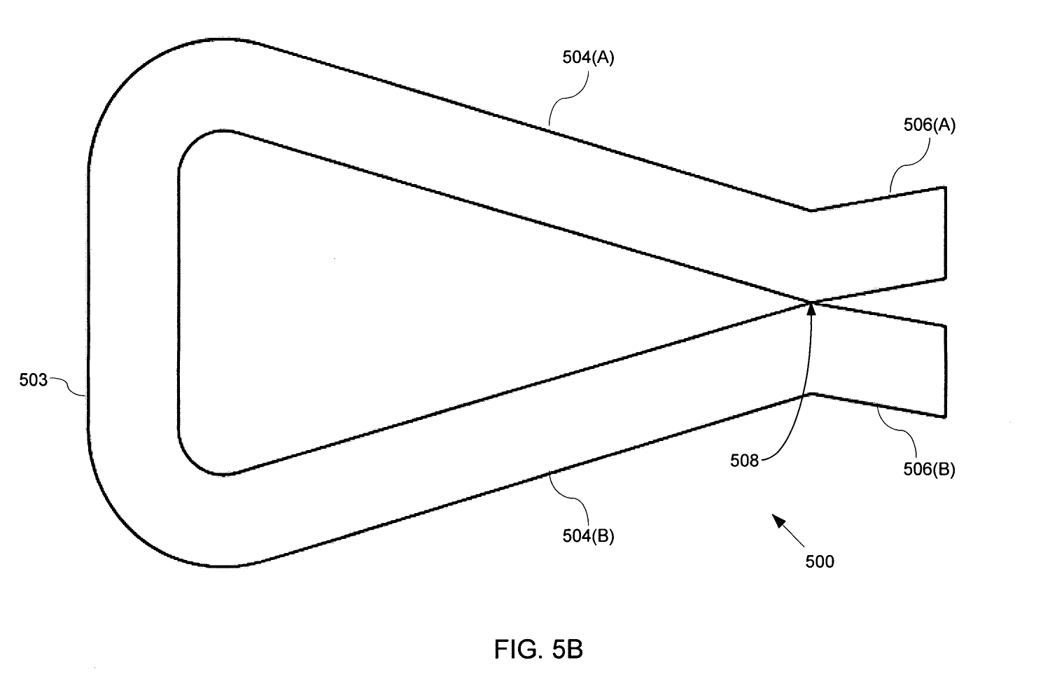

FIGS. 5A and 5B are three dimensional and side views, respectively, of yet another heat spreader clamping mechanism, according to yet another embodiment of the invention. This heat spreader clamping mechanism includes multiple separate and distinct clamps 500. Each clamp is applied separately to the heat spreader at a corresponding semiconductor device or opposing semiconductor devices. Each clamp 500 includes a pair of clamping arms 504(A) and 504(B) resiliently coupled to one another at a base 503, to form a triangular shape, such as the isosceles triangular shape shown. The arms are biased towards one another with a force sufficient to apply a uniform pressure to the heat spreader. This uniform pressure is transferred to thermal interface material. In some embodiments, the uniform pressure applied to the thermal interface material is between 10-40 psi, more preferably between 20-30 psi, and most preferably between 22-28 psi.

In some embodiments, the arms are shaped such that when not applied to the heat spreader, they contact one another at a contact 508. In some embodiments, this contact 508 is a contact line on each arm, while in other embodiments, the contact 508 is a contact point on each arm. In some embodiments, the contact 508 on each arm makes contact with the heat spreader at the center of each semiconductor device 106 (FIG. 1A).

When applying the clamp to the heat spreader, the ends 506(A) and 506(B) of each of the arms 504(A) and 504(B) are forced open away from one another so that the arms can straddle the heat spreader. A special tool may be required to force the arms 504 (A) and 504 (B) open when applying the heat spreader clamping mechanism to the heat spreader.

In some embodiments, the clamps 500 are fabricated using a blanking process. In this embodiment, the material used is 2 mm thick Al 6061 T6 sheet metal, which is cheap and easy to form. As before, the shape and size of this clamp 500 was optimized using an ANSYS FEA method. Also in some embodiments, the cross-section of this clip is about 2×2 mm square.

Furthermore, in an alternative embodiment, these clamps 500 are joined to a common spine, as per the embodiments shown in FIGS. 4A and 4B.

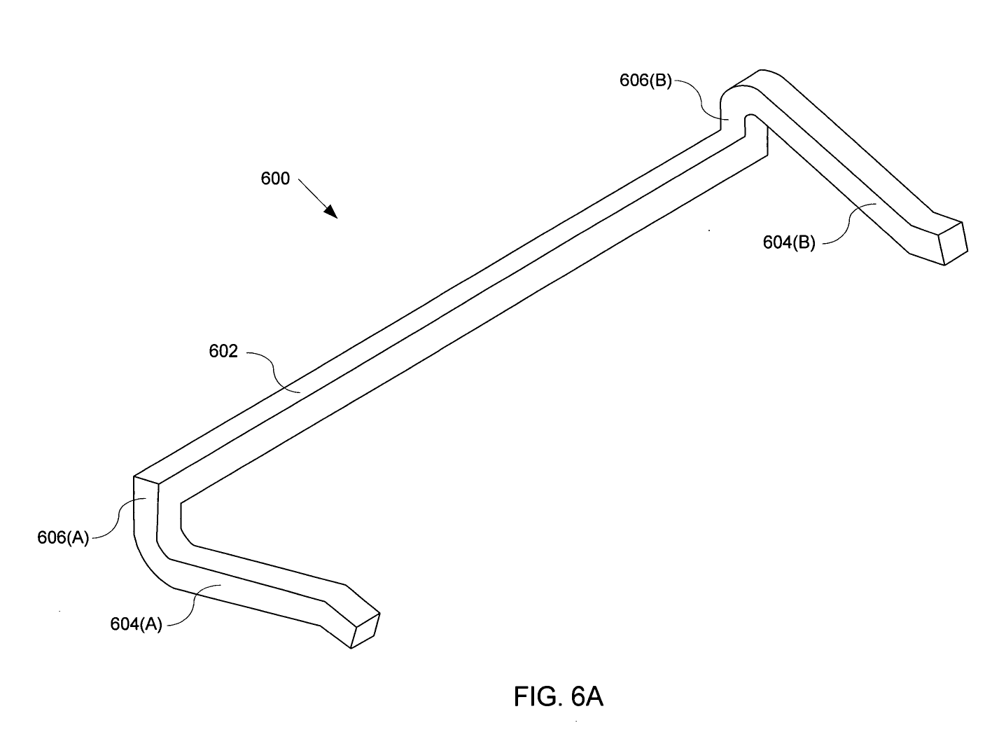

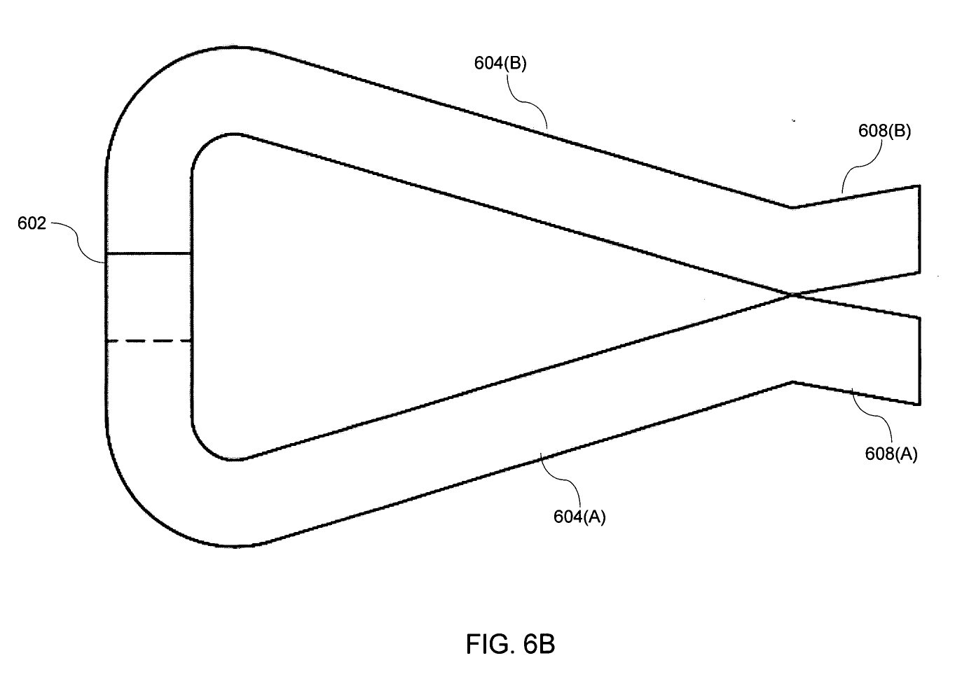

FIGS. 6A and 6B are three dimensional and side views, respectively, of one other heat spreader clamping mechanism, according to one other embodiment of the invention. This heat spreader clamping mechanism includes a single clamp 600. The clamp is applied across the length of the heat spreader. The clamp 600 includes a pair of offset clamping arms 604(A) and 604(B) resiliently coupled to one another via a first base 606(A), an elongate connecting bar 602 and a second base 606(B). The first arm 604(A) is coupled to the first base 606(A), while the second arm 604(B) is coupled to the second base 606(B). The first and second bases are coupled to one another via the connecting bar 602 that is disposed perpendicular to the arms. The arms are shaped such that they each contact the heat spreader at a point or line contact.

As the arms 604(A) and 604(B) are offset from one another by the length of the connecting bar 602, the clamp 600 may apply a torque to the heat spreader. To counteract this torque, two clamps 600 may be applied to the heat spreader, where the clamps face one another and the arms of respective clamps mirror each other on either side of the circuit board substrate.

The arms 604(A) and 604(B) are biased towards one another with a force sufficient to apply a uniform pressure to the heat spreader. This uniform pressure is transferred to thermal interface material. In some embodiments, the uniform pressure applied to the thermal interface material is between 10-40 psi, more preferably between 20-30 psi, and most preferably between 22-28 psi.

When applying the clamp to the heat spreader, the ends 608(A) and 608 (B) of each of the arms 604(A) and 604(B) are forced open away from one another so that the arms can straddle the heat spreader. A special tool may be required to force the arms 604 (A) and 604 (B) open when applying the clamp to the heat spreader. In some embodiments, the clamp 600 is made from Nitinol (NiTi), as described below. Also in some embodiments, the clamp 600 has a 2 mm by 2 mm cross-section.

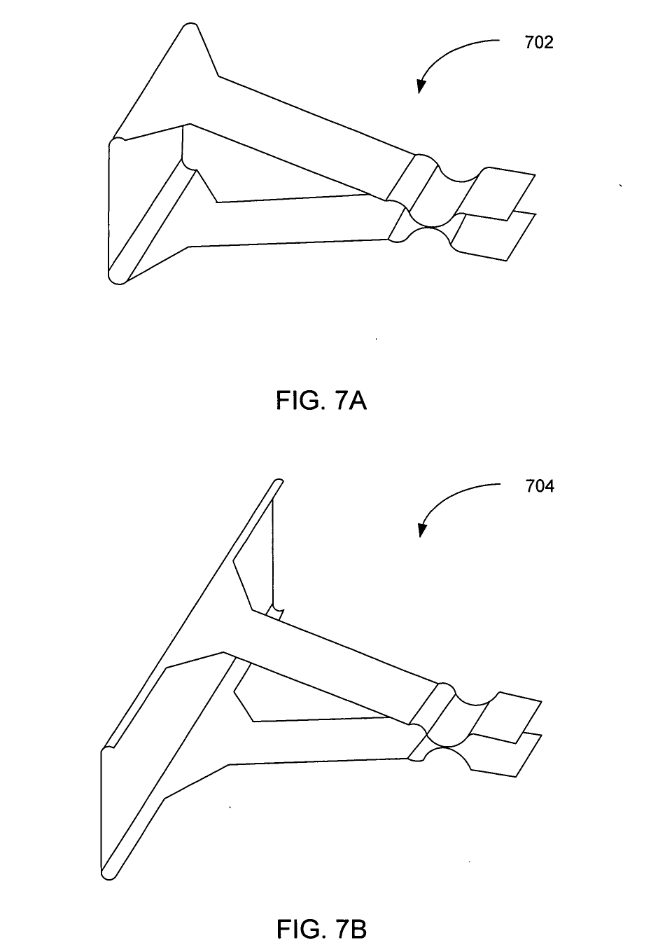

FIGS. 7A and 7B are two further embodiments of clamps 702 and 704, according to two other embodiments of the invention. Clamp 702 is similar to the heat spreader clamping mechanism 402 (FIG. 4A), except clamp 702 does not include multiple clamps connected to one another via a single spine. Clamp 704 is similar to clamp 702, except that clamp 704 has a limited spine, although this spine does not connect to other clamps. Each of the clamps 702 and 704 are applied separately to the heat spreader, in a manner similar to that described above in relation to FIGS. 5A and 5B. The clamps 702 and 704 may be made by stamping 301 stainless steel sheet metal with a 0.5 mm thickness.

Furthermore, any of the above-mentioned heat spreader clamping mechanisms or clamps may be manufactured from a shape memory alloy, such as Nitinol. However, the embodiment shown in FIG. 6 is particularly well suited to the use of Nitinol. Nitinol (an acronym for Nickel Titanium Naval Ordnance Laboratory) is a family of inter-metallic materials that contain a nearly equal mixture of nickel (55 wt. %) and titanium (balance). Nitinol exhibits a unique phase transformation in the crystal structure when transitioning between the Austenite and Martensite phases. The Austenite phase being the high temperature, stronger state compared to the weaker, low temperature Martensite phase. The most common two terms used to describe this behavior are “Superelasticity” and “Shape Memory”. Superelasticity occurs when Nitinol is mechanically deformed at a temperature above its Af (Austenite Finish) temperature. This deformation causes a stress-induced phase transformation from Austenite to Martensite. The stress-induced Martensite is unstable at temperatures above Af, so that when the stress is removed the material will immediately spring back to the Austenite phase and its pre-stressed position. Recoverable strains on the order of 8% are attainable. This high degree of elasticity, i.e. Superelasticity, is the most attractive property of Nitinol and the most common aspect of the material in use today.

The shape memory alloy clamp or clamping mechanism is easily formed at high temperatures into the desired shape with the help of a fixture or mandrel. Thereafter, at the operating temperature, which is less than 100 degrees Celsius and over martensitic transformation temperature in the embodiments described above, the shape memory alloy material is in the Austenite phase and has a strong tendency to return to its original shape once deformed. This large spring force is otherwise known as hyper-elasticity, which is a desirable characteristic for applying a uniform contact pressure on the heat spreader. The shape memory alloy also requires less material for the same spring force as compared to other materials.

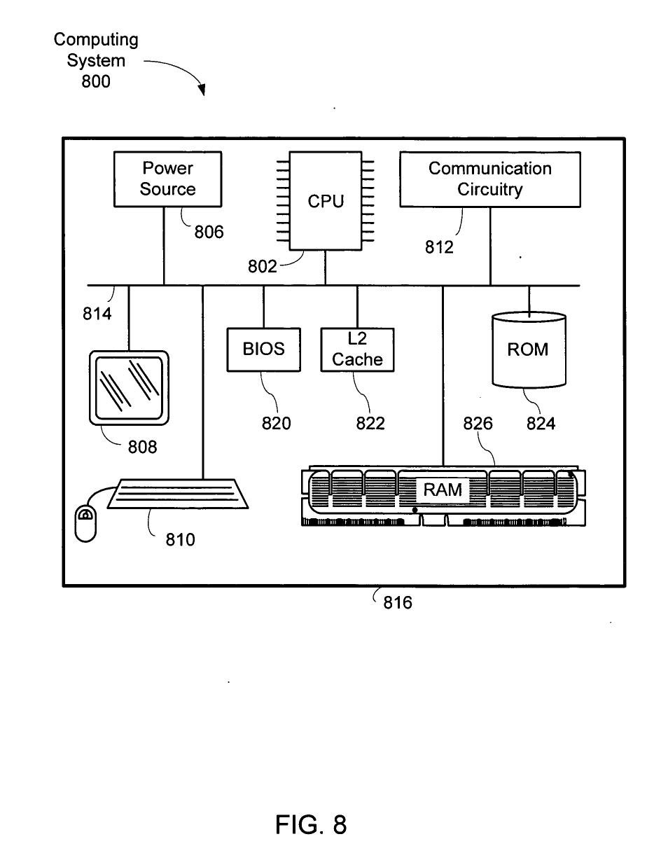

FIG. 8 is a block diagram of a system 800 that utilizes the heat spreader clamping mechanism of the present invention. The system 800 includes a plurality of components, such as at least one central processing unit (CPU) 802; a power source 806, such as a power transformer, power supply or batteries; input and/or output devices, such as a keyboard and mouse 808 and a monitor 810; communication circuitry 812; a BIOS 820; a level two (L2) cache 822; Read Only Memory (ROM) 824, such as a hard-drive; Random Access Memory (RAM) 826; and at least one bus 814 that connects the aforementioned components. These components are at least partially housed within a housing 816. The heat spreader clamping mechanism described above may be coupled to any of the components that produce heat, such as the CPU 802, BIOS 820, or ROM 824. However, in many embodiments, the heat spreader clamping mechanism is coupled to the RAM 826 semiconductor module, as shown.

Accordingly, some embodiments of the semiconductor module include a substrate having multiple semiconductor devices coupled to opposing sides thereof, and at least one thermal interface material layer at least partially covering the semiconductor devices. The semiconductor module also includes at least one heat spreader covering the at least one thermal interface material layer, and multiple clamps coupling the heat spreader to the thermal interface material with a substantially uniform pressure across all of the semiconductor devices.

Furthermore, other embodiments include a clamping mechanism for mechanically coupling a heat spreader to a layer of thermal interface material covering multiple dies of a semiconductor module. The clamping mechanism includes multiple clamps each having a pair of clamping arms resiliently coupled to one another and configured such that in use the clamping arms are biased towards one another with sufficient force to supply a substantially uniform pressure of between 20-30 psi to the thermal interface material.

Still further, some embodiments provide a clamp for mechanically coupling a heat spreader to a layer of thermal interface material covering multiple dies of a semiconductor module The clamp includes a pair of clamping arms resiliently coupled to one another and configured such that in use the clamping arms are biased towards one another with sufficient force to supply a substantially uniform pressure of between 20-30 psi to the thermal interface material.

Moreover, other embodiments provide a semiconductor module that includes a substrate having multiple semiconductor devices coupled to opposing sides thereof, and at least one thermal interface material layer at least partially covering the semiconductor devices. The semiconductor module also includes at least one heat spreader covering the at least one thermal interface material layer, and at least one clamp coupling the heat spreader to the thermal interface material with a pressure sufficient to dissipate at least 6 watts of power from the semiconductor devices.

In these embodiments, the pressure may be sufficient to dissipate at least 25 watts of power from the semiconductor devices. Also, the thermal interface material, the at least one heat spreader, and the at least one clamp may be configured to dissipate heat away from the semiconductor devices to keep the semiconductor devices cooler than 100 degrees Celsius.

The above described embodiments provide systems for efficiently and effectively dissipating heat away from high powered semiconductor devices. This allows semiconductor devices to operate at higher frequencies and to have higher capacities. This also allows more semiconductor devices to operate closer to one another. For example, some embodiments dissipate heat away from semiconductor modules that generate more than 6 watts of power, and other embodiments dissipate heat away from semiconductor modules that generate 10 watts, 25 watts or more. Also, some embodiments are configured such that the temperature of the semiconductor devices never rises above 100 degrees Celsius. Furthermore, the above-mentioned embodiments allow the assembled semiconductor module to be disassembled, if necessary.

While the foregoing description and drawings represent the preferred embodiments of the present invention, it will be understood that various additions, modifications and substitutions may be made therein without departing from the spirit and scope of the present invention as defined in the accompanying claims. In particular, it will be clear to those skilled in the art that the present invention may be embodied in other specific forms, structures, arrangements, proportions, and with other elements, materials, and components, without departing from the spirit or essential characteristics thereof. For example, the cross section of the individual clamps may be any shape, such as rectangular, round or square, and the exact shape and size of each clamp may be determined by FEA calculations. The presently disclosed embodiments are therefore to be considered in all respects as illustrative and not restrictive, the scope of the invention being indicated by the appended claims, and not limited to the foregoing description.

What is claimed is:

1. A semiconductor module comprising:
a circuit board substrate;
multiple semiconductor devices each having a semiconductor first side coupled to said substrate, and a semiconductor second side opposing said semiconductor first side;
a layer of thermal interface material having a thermal interface material first side at least partially covering said semiconductor second side, and a thermal interface material second side opposing said thermal interface material first side;
a heat spreader having a heat spreader first side contacting said thermal interface material second side, and a heat spreader second side opposing said heat spreader first side; and
at least one clamp coupled to said heat spreader, where said clamp is configured to force said heat spreader first side against said thermal interface material with a substantially uniform pressure across all of said semiconductor devices.

2. The semiconductor module of claim 1, wherein said substantially uniform pressure is between 10-40 psi.

3. The semiconductor module of claim 1, wherein said substantially uniform pressure is between 20-30 psi.

4. The semiconductor module of claim 1, wherein said substantially uniform pressure is between 22-28 psi.

5. The semiconductor module of claim 1, wherein said multiple semiconductor dies are coupled to opposing sides of said substrate.

6. The semiconductor module of claim 5, wherein said layer of thermal interface material comprises two sheets of thermal interface material, each of which extends across all of said multiple semiconductor devices on a respective side of said substrate.

7. The semiconductor module of claim 6, wherein said heat spreader comprises two parts, each part having at least one substantially flat heat spreader first side that contacts said thermal interface material on a respective side of said substrate.

8. The semiconductor module of claim 7, wherein said at least one clamp comprises multiple clamps spaced along said semiconductor module, where each clamp is configured to force both parts of said heat spreader against said thermal interface material with a substantially uniform pressure across all of said semiconductor devices.

9. The semiconductor module of claim 1, wherein said at least one clamp comprises multiple clamps spaced along said semiconductor module, where each clamp is configured to force both parts of said heat spreader against said thermal interface material with a substantially uniform pressure across all of said semiconductor devices.

10. The semiconductor module of claim 9, wherein each of said multiple clamps are coupled to one another via a common spine.

11. The semiconductor module of claim 10, wherein each of said multiple clamps comprises a pair of clamping arms resiliently coupled to, and biased toward, one another.

12. The semiconductor module of claim 11, wherein each of said clamping arms flare at a point where they couple to said spine.

13. The semiconductor module of claim 11, wherein each of said clamping arms forms an acute angle with a common base.

14. The semiconductor module of claim 13, wherein said base includes two parallel first members coupled together via a second member that is perpendicular to said first members.

15. The semiconductor module of claim 1, wherein said thermal interface material is a thermal interface material (TIM).

16. The semiconductor module of claim 1, wherein said heat spreader includes multiple heat dissipating fins.

17. The semiconductor module of claim 1, wherein said at least one clamp is removable.

18. The semiconductor module of claim 1, wherein said substrate is a multi-layer circuit board.

19. The semiconductor module of claim 1, wherein said at least one clamp comprises a pair of clamping arms resiliently coupled to one another and biased towards one another.

20. The semiconductor module of claim 1, wherein said at least one clamp includes as many clamps as there are semiconductor devices on each side of said substrate.

21. The semiconductor module of claim 1, wherein said at least one clamp has an isosceles triangle shape when viewed perpendicular to a longitudinal axis of said semiconductor module.

22. The semiconductor module of claim 1, wherein said semiconductor first side is coupled to said substrate via a ball grid array.

23. The semiconductor module of claim 1, wherein said at least one clamp is 0.5 mm thick SS301 stainless steel formed by a stamping process.

24. The semiconductor module of claim 1, wherein said at least one clamp has a 2×2 mm cross section, is AL 6061 T6 sheet metal, and is formed by a blanking process.

25. A semiconductor module comprising:
a substrate having multiple semiconductor devices coupled to opposing sides thereof;
a thermal interface material layer at least partially covering said semiconductor devices;
a heat spreader covering said thermal interface material layer; and
a means for coupling said heat spreader to said thermal interface material layer, where said means is configured to force said heat spreader against said thermal interface material layer with a substantially uniform pressure across all of said semiconductor devices.

26. A clamp for coupling a heat spreader to one or more semiconductor devices, where said clamp is made from a shape memory alloy.

27. The clamp of claim 26, wherein said shape memory alloy is Nitinol (NiTi).

28. A computing system comprising:
a bus;
a processor electrically coupled to said bus;
a semiconductor module electrically coupled to said bus, said semiconductor module comprising:
a substrate having multiple semiconductor devices coupled to opposing sides thereof;
at least one thermal interface material layer at least partially covering said semiconductor devices;
at least one heat spreader covering said at least one thermal interface material layer; and
multiple clamps coupling said heat spreader to said thermal interface material with a substantially uniform pressure across all of said semiconductor devices.

29. A method for dissipating heat from a plurality of semiconductor devices coupled to opposing sides of a substrate of a semiconductor module, said method comprising:
at least partially covering multiple semiconductor devices with a thermal interface material layer;
applying at least one heat spreader over said thermal interface material layer; and
applying a substantially uniform pressure across all of said semiconductor devices.

30. A semiconductor module comprising:
a substrate having multiple semiconductor devices coupled to opposing sides thereof;
at least one thermal interface material layer at least partially covering said semiconductor devices; and
at least one heat spreader covering said at least one thermal interface material layer, where said at least one heat spreader is configured to dissipate at least 6 watts away from said semiconductor devices.

31. The semiconductor device of claim 30, further comprising at least one clamp coupling said heat spreader to said thermal interface material with a substantially uniform pressure across all of said semiconductor devices.
